(19) United States
(12) Patent Application Publication
(10) Pub. No.: US 2026/0004819 A1
(43) Pub. Date: Jan. 1, 2026

(54) MEMORY DEVICE

(71) Applicant: Kioxia Corporation, Tokyo (JP)

(72) Inventor: Kosuke KASUGA, Yokkaichi Mie (JP)

(21) Appl. No.: 19/070,096

(22) Filed: Mar. 4, 2025

(30) Foreign Application Priority Data
Jun. 26, 2024 (JP) 2024-103086

(51) Int. Cl. G11C 5/06; G11C 16/04; H01L 23/00; H10B 43/10; H10B 43/27; H10B 43/35; H10B 43/40

(52) U.S. Cl. CPC G11C 5/063; G11C 16/0483; H01L 24/08; H10B 43/10; H10B 43/27; H10B 43/35; H10B 43/40; H01L 2224/08235

(57) ABSTRACT

A memory device includes a substrate; a first circuit layer provided between the substrate and a bonding surface and including a first circuit; a second circuit layer provided above the bonding surface and including a second circuit; and a wiring layer provided above the second circuit layer and including a plurality of first wirings and a plurality of second wirings, each of the first and second wirings extending in a first direction. The plurality of first wirings are electrically connected to at least one of the first circuit or the second circuit. The plurality of second wirings are electrically connected to each other. The first wirings and the second wirings are arranged alternately in a second direction along a substrate surface of the substrate, the second direction intersecting the first direction.

### CROSS-REFERENCE TO RELATED APPLICATION

This application is based upon and claims the benefit of priority from Japanese Patent Application No. 2024-103086, filed Jun. 26, 2024, the entire contents of which are incorporated herein by reference.

### FIELD

Embodiments described herein relate generally to a memory device.

### BACKGROUND

A NAND flash memory capable of storing data in a non-volatile manner is known.

### DESCRIPTION OF THE DRAWINGS

FIG. 1 is a block diagram showing an example of an overall configuration of a memory system including a memory device according to an embodiment.

FIG. 2 is a circuit diagram showing an example of a circuit configuration of a memory cell array provided in the memory device according to the embodiment.

FIG. 3 is a perspective view showing an example of an appearance of the memory device according to the embodiment.

FIG. 4 is a plan view showing an example of a planar layout of the memory device according to the embodiment.

FIG. 5 is a plan view showing an example of a planar layout in a core region of the memory cell array provided in the memory device according to the embodiment.

FIG. 6 is a cross-sectional view taken along line VI-VI in FIG. 5, showing an example of a cross-sectional structure in a memory area of the memory cell array provided in the memory device according to the embodiment.

FIG. 7 is a cross-sectional view taken along line VII-VII in FIG. 6, showing an example of a cross-sectional structure of a memory pillar provided in the memory device according to the embodiment.

FIG. 8 is a cross-sectional view showing an example of a cross-sectional structure of the memory device according to the embodiment.

FIG. 9 is a plan view showing an example of a planar layout of a wiring layer in the memory device according to the embodiment.

FIG. 10 is a plan view showing an example of a planar layout of source lines, power supply lines, and shield lines in the memory device according to the embodiment.

FIG. 11 is a cross-sectional view taken along line XI-XI in FIG. 10, showing an example of a cross-sectional structure of a shield line and its vicinity provided in the memory device according to the embodiment.

FIG. 12 is a cross-sectional view taken along line XII-XII in FIG. 10, showing an example of a cross-sectional structure of a shield line and its vicinity provided in the memory device according to the embodiment.

FIG. 13 is a schematic view showing an overview of a manufacturing method of the memory device according to the embodiment.

FIG. 14 is a plan view illustrating an overview of a test method of the memory device according to the embodiment.

FIG. 15 is a cross-sectional view showing an example of a gap defect occurring in a memory device having a bonding structure.

FIG. 16 is a plan view showing an example of a planar layout of a wiring layer in a memory device according to a comparative example.

FIG. 17 is a plan view showing an example of a planar layout of source lines, power supply lines, and shield lines in a memory device according to a first modification example of the embodiment.

FIG. 18 is a plan view showing an example of a planar layout of source lines, power supply lines, and shield lines in a memory device according to a second modification example of the embodiment.

FIG. 19 is a cross-sectional view showing an example of a detailed cross-sectional structure of the vicinity of two bonding pads disposed opposite to each other in the memory device according to the embodiment.

### DETAILED DESCRIPTION

In general, according to one embodiment, there is provided a memory device. The memory device includes a substrate; a first circuit layer provided between the substrate and a bonding surface and including a first circuit; a second circuit layer provided above the bonding surface and including a second circuit; and a wiring layer provided above the second circuit layer and including a plurality of first wirings and a plurality of second wirings, each of the first and second wirings extending in a first direction. The plurality of first wirings are electrically connected to at least one of the first circuit or the second circuit. The plurality of second wirings are electrically connected to each other. The first wirings and the second wirings are arranged alternately in a second direction along a substrate surface of the substrate, the second direction intersecting the first direction.

Hereinafter, an embodiment will be described with reference to the drawings. The embodiment illustrates a device or a method for embodying the technical scope of the disclosure. The drawings are schematic or conceptual. The dimensions, ratios, and the like of each drawing are not necessarily the same as the actual ones. The configuration is not shown in the drawing as appropriate. The hatches added to the plan view are not necessarily related to the materials and properties of the elements. In the present specification, the same reference numerals are added to the elements having substantially the same function and configuration. Numbers, characters, and the like added to the reference code are referenced by the same reference code and are used to distinguish between similar elements.

### <1> Configuration

First, a configuration of a memory device 1 according to an embodiment will be described.

### <1-1> Overall Configuration of Memory Device 1

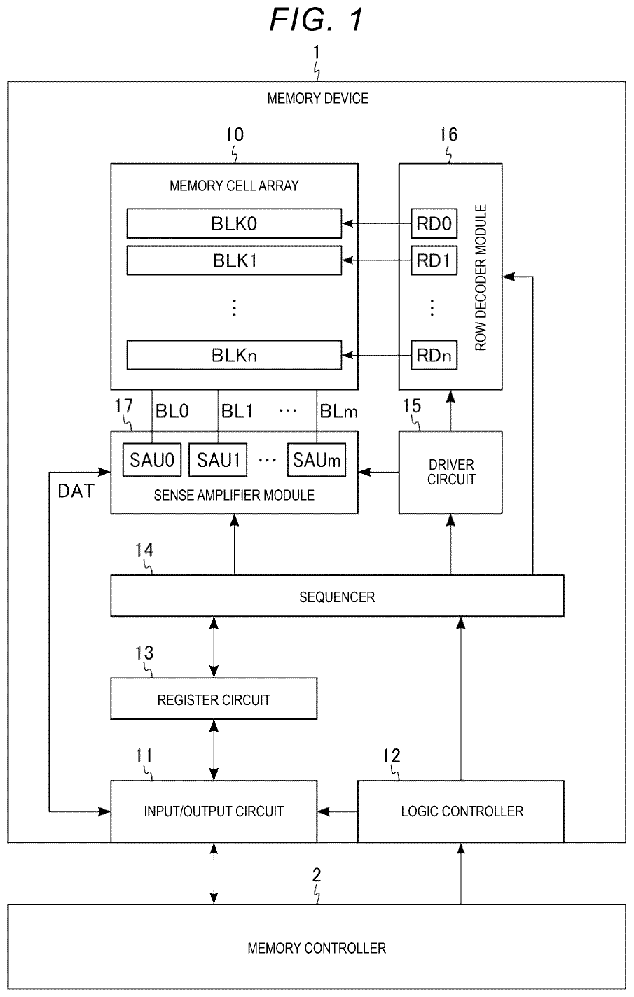

FIG. 1 is a block diagram showing an example of an overall configuration of a memory system including the memory device 1 according to the embodiment. As shown in FIG. 1, a memory device 1 is controlled by an external memory controller 2. The memory device 1 is, for example, a NAND flash memory capable of storing data in a non-volatile manner. The memory device 1 includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer equal to or greater than 1). The block BLK is a set of a plurality of memory cells. The block BLK corresponds to, for example, a unit of data erasure. The block BLK includes a plurality of pages. The page corresponds to a unit in which data is read and written. Although not shown, the memory cell array 10 is provided with a plurality of bit lines BL0 to BLm (where “m” is an integer equal to or greater than 1) and a plurality of word lines WL. Each memory cell is, for example, associated with one bit line BL and one word line WL.

The input/output circuit 11 is an interface circuit that controls to transmit and receive input/output signals to and from the memory controller 2. The input/output signals include, for example, data DAT, status information, address information, commands, and the like. The input/output circuit 11 can input and output data DAT between the sense amplifier module 17 and the memory controller 2, respectively. The input/output circuit 11 can output the status information transferred from the register circuit 13 to the memory controller 2. The input/output circuit 11 can output each of the address information and the command transferred from the memory controller 2 to the register circuit 13.

The logic controller 12 controls each of the input/output circuit 11 and the sequencer 14 based on a control signal input from the memory controller 2. For example, the logic controller 12 controls the sequencer 14 to enable the memory device 1. The logic controller 12 notifies the input/output circuit 11 that the input/output signal received by the input/output circuit 11 is a command, address information, or the like. The logic controller 12 instructs the input/output circuit 11 to input or output an input/output signal.

The register circuit 13 temporarily stores status information, address information, and commands. The status information is updated under the control of the sequencer 14 and transferred to the input/output circuit 11. The address information includes a block address, a page address, a column address, and the like. The commands include instructions regarding various operations of the memory device 1.

The sequencer 14 controls the overall operation of the memory device 1. The sequencer 14 executes a read operation, a write operation, an erase operation, and the like based on the command and address information stored in the register circuit 13.

The driver circuit 15 generates voltages used in a read operation, a write operation, an erase operation, and the like. The driver circuit 15 then supplies the generated voltage to the row decoder module 16, the sense amplifier module 17, and the like.

The row decoder module 16 is a circuit used for selecting a block BLK to be operated and for transferring a voltage to a wiring such as a word line WL. The row decoder module 16 includes a plurality of row decoders RD0 to RDn. The row decoders RD0 to RDn are associated with blocks BLK0 to BLKn, respectively, and are used to select the block BLK. Each row decoder RD transfers the voltage generated by the driver circuit 15 to various wirings provided in the memory cell array 10.

The sense amplifier module 17 is a circuit used for transferring a voltage to each bit line BL and for reading data. The sense amplifier module 17 includes a plurality of sense amplifier units SAU0 to SAUm. The sense amplifier units SAU0 to SAUm are associated with a plurality of bit lines BL0 to BLm, respectively. Each sense amplifier unit SAU includes a sense amplifier capable of determining data based on the voltage of an associated bit line BL, a latch circuit for temporarily latching data, and the like.

The combination of the memory device 1 and the memory controller 2 may constitute one semiconductor device. Examples of such semiconductor devices include memory cards such as SD™ cards and solid state drives (SSDs).

### <1-2> Circuit Configuration of Memory Cell Array 10

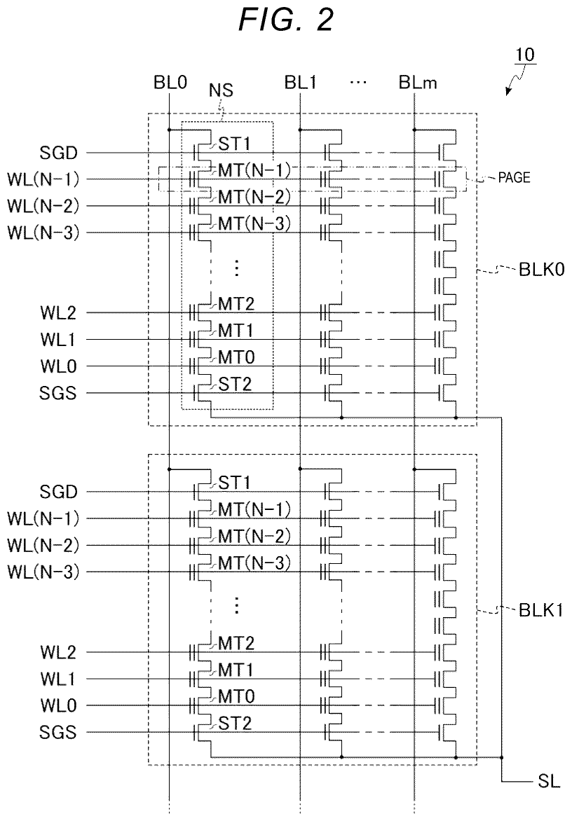

FIG. 2 is a circuit diagram showing an example of a circuit configuration of the memory cell array 10 provided in the memory device 1 according to the embodiment. FIG. 2 shows two blocks BLK0 and BLK1 out of the plurality of blocks BLK provided in the memory cell array 10. As shown in FIG. 2, in the memory cell array 10, select gate lines SGD and SGS and word lines WL0 to WL (N−1) (N is an integer equal to or greater than 2) are provided for each block BLK. The bit lines BL0 to BLm and a source line SL are shared by, for example, a plurality of blocks BLK.

Each block BLK includes a plurality of NAND strings NS. A plurality of NAND strings NS are associated with the bit lines BL0 to BLm, respectively. In other words, each bit line BL is shared by NAND strings NS to which the same column address is assigned among a plurality of blocks BLK. Each NAND string NS is connected between an associated bit line BL and a source line SL. Each NAND string NS includes, for example, N memory cell transistors MT0 to MT(N−1) and select transistors ST1 and ST2. Each memory cell transistor MT is a memory cell having a control gate and a charge storage layer, and latches (stores) data in a non-volatile manner. Each of the select transistors ST1 and ST2 is used to select a block BLK.

In each NAND string NS, the select transistor ST1, the memory cell transistors MT(N−1) to MT0, and the select transistor ST2 are connected in series in this order. Specifically, the drain terminal and the source terminal of the select transistor ST1 are connected to the associated bit line BL and the drain terminal of the memory cell transistor MT(N−1), respectively. The drain terminal and the source terminal of the select transistor 2 are connected to the source terminal of the memory cell transistor MT0 and the source line SL, respectively. The memory cell transistors MT0 to MT(N−1) are connected in series between the select transistors ST1 and ST2.

Each select gate line SGD is connected to the gate terminal of each of the plurality of select transistors ST1 provided in the associated block BLK. The select gate line SGS is connected to the gate terminal of each of the plurality of select transistors ST2 provided in the associated block BLK. The word lines WL0 to WL (N−1) are respectively connected to the respective control gate terminals of the plurality of memory cell transistors MT0 to MT(N−1) provided in the associated block BLK. A “page” corresponds to a set of a plurality of memory cell transistors MT connected to a common word line WL in the same block BLK. A set of a plurality of memory cell transistors MT connected to a common word line WL in the same block BLK may have a storage capacity of two or more pages of data depending on the number of bits stored in the memory cell transistors MT.

The memory cell array 10 may have another circuit configuration. For example, each block BLK may be provided with a plurality of select gate lines SGD that can be controlled independently. In this case, each block BLK is configured to be selectable in units of a plurality of units each corresponding to a plurality of select gate lines SGD.

In the following, the memory device 1 according to the embodiment will be described using an example in which each NAND string NS has eight memory cell transistors MT0 to MT7 connected to word lines WL0 to WL7, respectively (that is, N=8).

### <1-3> Structure of Memory Device 1

Hereinafter, a structure of the memory device 1 according to the embodiment will be described.

In the drawings referred to below, a three-dimensional Cartesian coordinate system is used. An X direction corresponds to an extension direction of the word lines WL. A Y direction corresponds to an extension direction of the bit lines BL. A Z direction corresponds to a vertical direction to the front surface of a semiconductor substrate which is used as a reference. “Up and down” are defined based on the direction along the Z direction. A positive direction (upward) corresponds to a direction away from the semiconductor substrate which is used as the reference. An XY plane (cross section) corresponds to a plane (cross section) parallel to each of the X direction and the Y direction. A YZ cross section corresponds to a cross section parallel to each of the Y direction and the Z direction. An XZ cross section corresponds to a cross section parallel to each of the X direction and the Z direction.

### 1: Appearance of Memory Device 1

First, an appearance of the memory device 1 according to the embodiment will be described. The memory device 1 according to the embodiment is formed by bonding two semiconductor circuit substrates, each having a semiconductor circuit formed thereon, and then separating the bonded semiconductor circuit substrates into individual chips. That is, the memory device 1 according to the embodiment has a bonding surface formed by bonding semiconductor substrates W1 and W2. Each of the semiconductor substrates W1 and W2 is a silicon substrate. In the following, a case in which the semiconductor substrate W2 is removed in the manufacturing process of the memory device 1 will be described. Depending on the structure of the memory cell array 10, a part of the semiconductor substrate W2 may remain after bonding the semiconductor substrates W1 and W2.

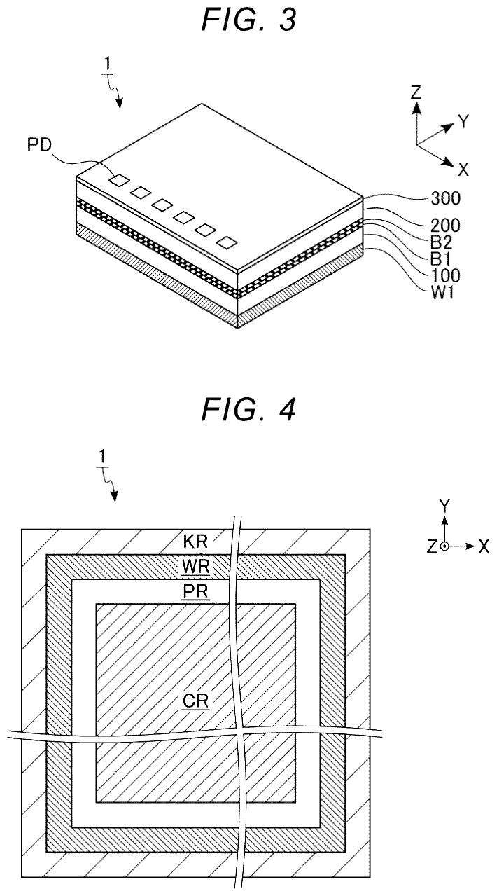

FIG. 3 is a perspective view showing an example of the appearance of the memory device 1 according to the embodiment. As shown in FIG. 3, the memory device 1 includes, for example, a semiconductor substrate W1, a CMOS layer 100, a bonding layer B1, a bonding layer B2, a memory layer 200, and a wiring layer 300.

The CMOS layer 100 is disposed on the semiconductor substrate W1. The CMOS layer 100 includes a CMOS circuit (control circuit) formed by utilizing the semiconductor substrate W1. The semiconductor substrate W1 has an impurity diffusion area and the like in accordance with the design of the CMOS circuit. The CMOS layer 100 includes, for example, an input/output circuit 11, a logic controller 12, a register circuit 13, a sequencer 14, a driver circuit 15, a row decoder module 16, and a sense amplifier module 17. The CMOS layer 100 may be referred to as a circuit layer.

The bonding layer B1 is disposed on the CMOS layer 100. The bonding layer B1 is formed by utilizing the semiconductor substrate W1. The bonding layer B1 includes a plurality of bonding pads that are electrically connected to the CMOS circuit provided in the CMOS layer 100 to form a portion of the semiconductor circuit.

The bonding layer B2 is disposed on the bonding layer B1. The bonding layer B2 is formed by utilizing a semiconductor substrate W2 (not shown). The bonding layer B2 includes a plurality of bonding pads that are electrically connected to the memory cell array 10 provided in the memory layer 200 to form a portion of the semiconductor circuit. A plurality of bonding pads provided in the bonding layer B2 are respectively connected to a plurality of bonding pads provided in the bonding layer B1. The area between the bonding layers B1 and B2 corresponds to a boundary portion between a layer formed using the semiconductor substrate W1 and a layer formed using the semiconductor substrate W2, that is, the bonding surface.

The memory layer 200 is disposed on the bonding layer B2. The memory layer 200 includes the memory cell array 10 or the like formed by utilizing the semiconductor substrate W2. The memory layer 200 may be referred to as a circuit layer.

The wiring layer 300 is disposed on the memory layer 200. The wiring layer 300 is formed after the semiconductor substrates W1 and W2 are bonded together. The wiring layer 300 includes a wiring connected to the semiconductor circuits provided in the memory layer 200 and a plurality of pads PD. The plurality of pads PD are exposed on the front surface of the memory device 1. The plurality of pads PD are used for connection with the memory controller 2, and the like, supply of power, and the like.

### 2: Planar Layout of Memory Device 1

FIG. 4 is a plan view showing an example of a planar layout of the memory device 1 according to the embodiment. As shown in FIG. 4, the memory device 1 includes, for example, a core region CR, a peripheral region PR, a wall region WR, and a kerf region KR.

For example, the core region CR is a rectangular region provided in the vicinity of the center of the semiconductor substrate W1. In the core region CR, for example, the memory cell array 10, the register circuit 13, the sequencer 14, the driver circuit 15, the row decoder module 16, the sense amplifier module 17, and the like are disposed.

The peripheral region PR is a quadrangular ring-shaped region that surrounds the outer periphery of the core region CR. In the peripheral region PR, for example, the input/output circuit 11, the logic controller 12, and the like are disposed. In addition, in the peripheral region PR, for example, contacts for connecting wiring provided in the wiring layer 300 to circuits provided in the CMOS layer 100 and the memory layer 200 are disposed.

The wall region WR is a quadrangular ring-shaped region that surrounds the outer periphery of the peripheral region PR. At least one sealing portion ES (not shown) is disposed in the wall region WR to surround the outer periphery of the peripheral region PR. Details of the sealing portion ES will be described later. The kerf region KR is a quadrangular ring-shaped region that surrounds the outer periphery of the wall region WR. The kerf region KR is in contact with the outermost periphery of the memory device 1. In the kerf region KR, for example, alignment marks and the like used during the manufacture of the memory device 1 are disposed. The structure of the kerf region KR may be removed by a dicing step, which will be described later.

### 3: Planar Layout of Memory Cell Array 10

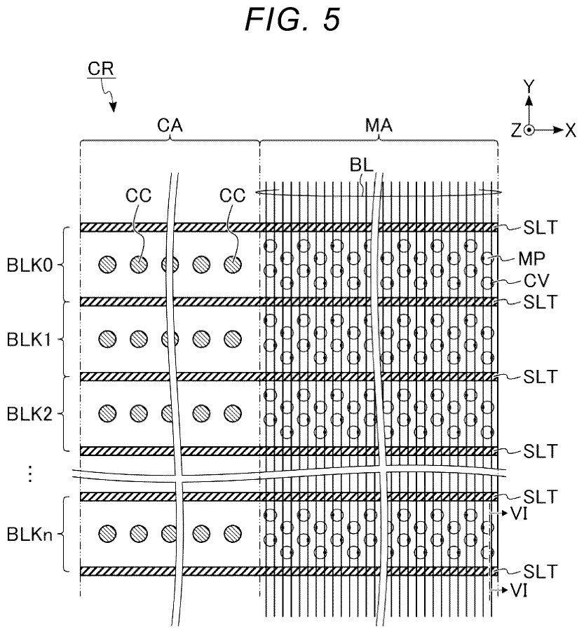

FIG. 5 is a plan view showing an example of a planar layout in the core region CR of the memory cell array 10 provided in the memory device 1 according to the embodiment. As shown in FIG. 5, the memory cell array 10 includes a plurality of slits SLT, a plurality of memory pillars MP, and a plurality of contacts CV and CC. The memory cell array 10 also includes, for example, a memory area MA and a contact area CA arranged in the X direction.

Each slit SLT is a plate-like member extending along the X direction. Each slit SLT has a portion extending along the X direction, and crosses the memory area MA and the contact area CA along the X direction. The plurality of slits SLTs are arranged in the Y direction. Each slit SLT divides adjacent wirings (for example, word lines WL0 to WL7 and select gate lines SGD and SGS) via the slit SLT. In each slit SLT, a conductor having an insulating spacer provided on the side wall may be insulated from these wirings, or an insulator may be embedded. In the memory cell array 10, each of the areas partitioned along the Y direction by the slits SLT corresponds to one block BLK.

The memory area MA is an area used for storing data. In the memory area MA, a plurality of memory pillars MP are disposed. Each memory pillar MP is, for example, a pillar shaped member that functions as one NAND string NS. A plurality of memory pillars MP are disposed in a lattice pattern for each block BLK. At least one bit line BL overlaps each memory pillar MP. The plurality of bit lines BL each have a portion extending in the Y direction, and are arranged in the X direction. In the present example, two bit lines BL overlap one memory pillar MP. The associated memory pillar MP and bit line BL are electrically connected via a contact CV.

The contact area CA is an area used for connection between the stacked wiring (for example, the word lines WL, the select gate lines SGD and SGS) provided in the memory cell array 10 and the row decoder module 16. In the contact area CA, a plurality of contacts CC are disposed for each block BLK. For each block BLK, each of the plurality of contacts CC is electrically connected to one associated wiring among the stacked wirings. In each block BLK, at least one contact CC is electrically connected to each of the select gate line SGS, the word lines WL0 to WL7, and the select gate line SGD. In the contact area CA, the plurality of contacts CC in each block BLK are not limited to being disposed in a line in the X direction as shown in FIG. 5, but may be disposed in a lattice pattern for each block BLK.

### 4: Cross-Sectional Structure in Memory Area MA of Memory Cell Array 10

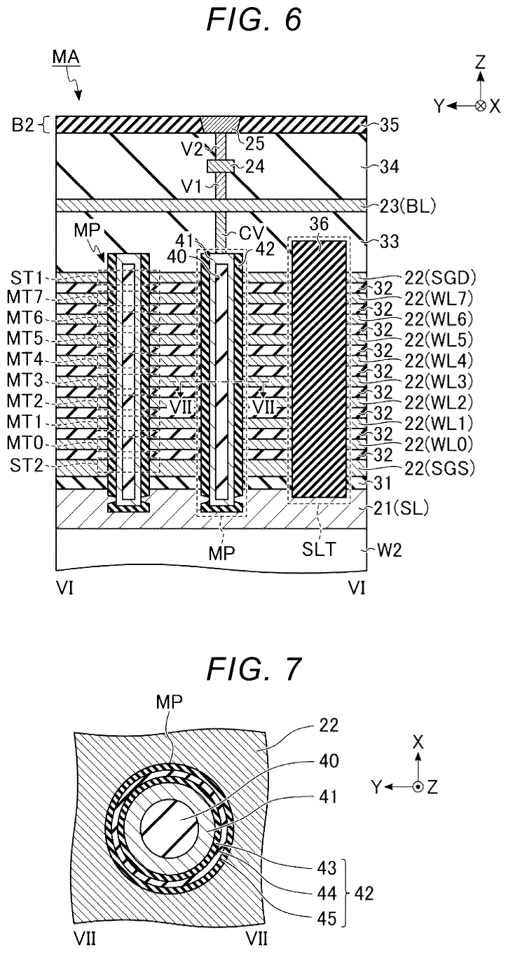

FIG. 6 is a cross-sectional view taken along line VI-VI in FIG. 5, showing an example of a cross-sectional structure in the memory area MA of the memory cell array 10 provided in the memory device 1 according to the embodiment. FIG. 6 shows an example of the structure of the memory cell array 10 formed on the semiconductor substrate W2 before being bonded to the semiconductor substrate W1, and indicates coordinate axes with the semiconductor substrate W2 as a reference. As shown in FIG. 6, the memory cell array 10 includes, for example, conductive layers 21 to 25, insulator layers 31 to 35, an insulating member 36, and contacts CV, V1, and V2 in the memory area MA.

The conductive layer 21 is provided on the semiconductor substrate W2. The insulator layer 31 is provided on the conductive layer 21. On the insulator layer 31, the conductive layer 22 and the insulator layer 32 are provided alternately. That is, a plurality of conductive layers 22 are arranged in the Z direction. The number of layers of the conductive layer 22 corresponds to, for example, the number of layers of the stacked wiring (select gate line SGS, word line WL, and select gate line SGD). On the uppermost conductive layer 22, the insulator layer 33, the conductive layer 23, the insulator layer 34, and the insulator layer 35 are provided in this order. Each of the conductive layers 21 and 22 is formed, for example, in a plate shape extending along the XY plane. The conductive layer 23 has, for example, a portion formed in a line shape extending in the Y direction. The conductive layer 21 is used as a part of a source line SL. In the present example, the ten conductive layers 22 arranged in the Z direction are used as, in order from the source line SL side, a select gate line SGS, word lines WL0 to WL7, and a select gate line SGD. The conductive layer 23 is used as a bit line BL. The conductive layer 21 includes, for example, polysilicon (Si). The conductive layer 22 includes, for example, tungsten (W). The conductive layer 23 includes, for example, copper (Cu).

The conductive layer 24 is provided above the conductive layer 23. The conductive layer 24 is a wiring that relays the connection between the bit line BL and the sense amplifier module 17. The conductive layer 23 and the conductive layer 24 are connected via the contact V1. The conductive layer 25 is provided above the conductive layer 24. The conductive layer 25 corresponds to the bonding pad. The conductive layer 24 and the conductive layer 25 are connected via the contact V2. The side surfaces of the conductive layer 24 and the contacts V1 and V2 are covered with the insulator layer 34. The insulator layer 34 may be configured with a plurality of insulating films. The side surfaces of the conductive layer 25 are covered with the insulator layer 35. The insulator layer 35 and the conductive layer 25 are provided in the bonding layer B2. The memory cell array 10 may include a plurality of conductive layers 24 and a plurality of conductive layers 25. The conductive layer 25 includes, for example, copper.

The insulating member 36 has a portion formed in a plate shape extending along an XZ plane. The insulating member 36 divides the insulator layer 31 and the conductive layers 22 and the insulator layers 32 that are alternately provided. In the present example, the insulating member 36 is embedded in the slit SLT. In the slit SLT, a conductor having an insulating spacer provided on the side wall and the bottom surface may be insulated from each of the conductive layers 21 and 22.

Each memory pillar MP extends along the Z direction, and penetrates the insulator layer 31 and the conductive layers 22 and the insulator layers 32 that are provided alternately, and is connected to the conductive layer 21. Each memory pillar MP includes, for example, a core member 40, a semiconductor layer 41, and a stacked film 42. The core member 40 is an insulator extending along the Z direction. The semiconductor layer 41 covers the core member 40. A part of the side surface of the semiconductor layer 41 is in contact with the conductive layer 21. That is, the semiconductor layer 41 in the memory pillar MP and the conductive layer 21 (source line SL) are connected via the side surface of the memory pillar MP. The stacked film 42 covers the side surface and the bottom surface of the semiconductor layer 41 except for a contact portion between the semiconductor layer 41 and the conductive layer 21. The associated semiconductor layer 41 (memory pillar MP) and the conductive layer 23 (bit line BL) are connected via the contact CV.

The portion where the conductive layer 22 used as the select gate line SGS intersects with the memory pillar MP functions as a select transistor ST2. The portion where the conductive layer 22 used as the word line WL intersects with the memory pillar MP functions as a memory cell transistor MT. The portion where the conductive layer 22 used as the select gate line SGD intersects with the memory pillar MP functions as a select transistor ST1. In each memory pillar MP, the semiconductor layer 41 is used as a channel (current path) for the memory cell transistors MT0 to MT7 and the select transistors ST1 and ST2 provided in the NAND string NS.

### 5: Cross-Sectional Structure of Memory Pillar MP

FIG. 7 is a cross-sectional view taken along line VII-VII in FIG. 6, showing an example of a cross-sectional structure of the memory pillar MP provided in the memory device 1 according to the embodiment. FIG. 7 shows a cross section including the memory pillar MP and the conductive layer 22 and parallel to the front surface of the semiconductor substrate W2. As shown in FIG. 7, the stacked film 42 includes, for example, a tunnel insulating film 43, an insulating film 44, and a block insulating film 45. The tunnel insulating film 43 surrounds the side surface of the semiconductor layer 41. The insulating film 44 surrounds the side surface of the tunnel insulating film 43. The block insulating film 45 surrounds the side surface of the insulating film 44. The conductive layer 22 surrounds the side surface of the block insulating film 45. Each of the tunnel insulating film 43 and the block insulating film 45 includes, for example, silicon oxide (SiO₂). The insulating film 44 is used as a charge storage layer for the memory cell transistor MT. The insulating film 44 includes, for example, silicon nitride (SiN).

### 6: Cross-Sectional Structure of Memory Device 1

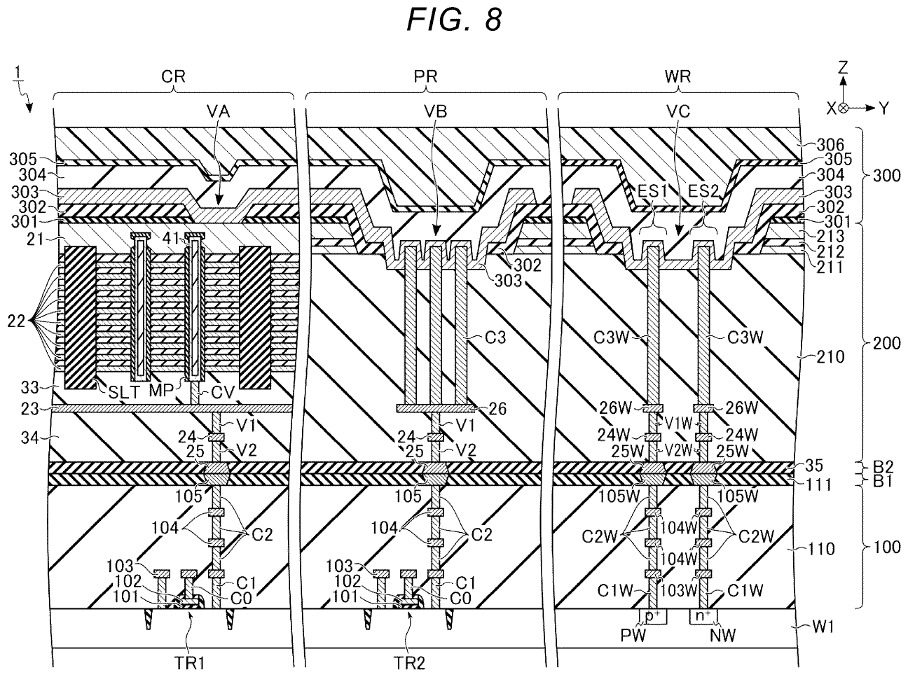

FIG. 8 is a cross-sectional view showing an example of a cross-sectional structure of the memory device 1 according to the embodiment. FIG. 8 shows a part of the core region CR, the peripheral region PR, and the wall region WR after the semiconductor substrate W1 and the semiconductor substrate W2 are bonded, and indicates coordinate axes with the semiconductor substrate W1 as a reference. In the present example, the semiconductor substrate W2 is removed after the bonding process of the semiconductor substrates W1 and W2. The memory layer 200 and the bonding layer B2 have a structure in which the structure related to the memory cell array 10 shown in FIG. 6 is disposed upside down in the core region CR. As shown in FIG. 8, the CMOS layer 100 includes an insulator layer 110. The bonding layer B1 includes an insulator layer 111. The memory layer 200 includes an insulator layer 210, a conductive layer 211, a sacrificial member 212, and a conductive layer 213. The wiring layer 300 includes an insulator layer 301, an insulator layer 302, a conductive layer 303, an insulator layer 304, an insulator layer 305, and an insulator layer 306.

The insulator layer 110 is provided on the semiconductor substrate W1. The insulator layer 110 covers at least a part of the wiring, contacts, elements, and the like provided in the CMOS layer 100. The insulator layer 110 may be configured with a plurality of types of insulating films. The insulator layer 111 is provided on the insulator layer 110. The insulator layer 111 covers the side surfaces of the bonding pads provided on the bonding layer B1. On the insulator layer 111, the insulator layer 35 of the bonding layer B2 is provided. The insulator layer 210 is provided on the insulator layer 35. The insulator layer 210 covers at least a part of the wiring, contacts, elements, and the like provided in the memory layer 200. The insulator layer 210 may be configured with a plurality of types of insulating films, and may include the insulator layers 33 and 34. On the insulator layer 210, the conductive layer 211, the sacrificial member 212, and the conductive layer 213 are stacked in this order. The set of the conductive layer 211, the sacrificial member 212, and the conductive layer 213 is provided at the same height as the conductive layer 21. Specifically, the height of the lower surface of the conductive layer 211 is aligned with the height of the lower surface of the conductive layer 21 (source line SL). The height of the upper surface of the conductive layer 213 is aligned with the height of the upper surface of the conductive layer 21 (source line SL). The conductive layer 21 in the core region CR corresponds to a structure in which the conductive layer 211, the sacrificial member 212, and the conductive layer 213 are stacked, and then the sacrificial member 212 is replaced with a conductor. That is, the height of the sacrificial member 212 is the same as the height at which the conductive layer 21 and the semiconductor layer 41 in each memory pillar MP are connected. Each of the conductive layers 211 and 213 includes, for example, polysilicon (Si). The sacrificial member 212 includes, for example, silicon nitride (SiN).

The insulator layer 301, the insulator layer 302, the conductive layer 303, the insulator layer 304, the insulator layer 305, and the insulator layer 306 are provided in this order on the conductive layer 213 and the conductive layer 21. The conductive layer 303 is divided (insulated) between the peripheral region PR and the wall region WR. The conductive layer 303 may be divided (insulated) between the core region CR and the peripheral region PR, or may be continuously provided. Each of the insulator layers 301, 302, and 304 includes, for example, a silicon oxide (SiO₂). The insulator layer 305 includes, for example, silicon nitride (SiN). The insulator layer 306 includes, for example, polyimide.

The wiring layer 300 includes a via VA in the core region CR, a via VB in the peripheral region PR, and a via VC in the wall region WR. The via VA penetrates the insulator layers 301 and 302. The conductive layer 303 in the core region CR may have a portion in contact with the conductive layer 21 through the via VA. The via VB penetrates the conductive layer 211, the sacrificial member 212, the conductive layer 213, and the insulator layers 301 and 302. The conductive layer 303 in the peripheral region PR may have a portion in contact with the contact C3, which will be described later, through the via VB. The portion of the conductive layer 303 provided in the via VB is insulated from the conductive layers 211 and 213 by the insulator layer 302. The via VC penetrates the conductive layer 211, the sacrificial member 212, the conductive layer 213, and the insulator layers 301 and 302. The conductive layer 303 in the wall region WR has a portion in contact with sealing portions ES1 and ES2, which will be described later, through the via VC. The portion of the conductive layer 303 provided in the via VC is insulated from the conductive layers 211 and 213 by the insulator layer 302.

In the core region CR, the CMOS layer 100 includes a gate insulating film 101, a gate electrode 102, conductive layers 103 and 104, and contacts C0 to C2, and the bonding layer B1 includes a conductive layer 105. The gate insulating film 101 is provided on the semiconductor substrate W1. The gate electrode 102 in the core region CR is provided on the gate insulating film 101 and is used as the gate electrode of the transistor TR1. The transistor TR1 is provided in, for example, the sense amplifier module 17. The conductive layer 103 is a wiring layer above the gate electrode 102. The contact C0 connects the gate electrode 102 to the conductive layer 103. The contact C0 connects the impurity diffusion area of the transistor TR1 provided in the semiconductor substrate W1 to the conductive layer 103. The conductive layer 104 is a wiring provided at a height between the conductive layer 103 and the bonding layer B1. The contact C2 is provided at a height between the conductive layer 103 and the bonding layer B1. At least one conductive layer 103 is connected to the conductive layer 105 via at least one contact C2 and at least one conductive layer 104. The conductive layer 105 corresponds to the bonding pad disposed in the bonding layer B1. The conductive layer 105 is in contact with the conductive layer 25 disposed opposite the conductive layer 105 in the bonding layer B2. Accordingly, the semiconductor layer 41 in the core region CR is electrically connected to the transistor TR1 via the contact CV, the conductive layers 23 to 25 and 103 to 105, and the contacts CV, V1, V2, C1, and C2.

In the peripheral region PR, the CMOS layer 100 includes a gate insulating film 101, a gate electrode 102, conductive layers 103 and 104, and contacts C0 to C2, and the bonding layer B1 includes a conductive layer 105, similarly to the core region CR. The gate electrode 102 in the peripheral region PR is used as the gate electrode of the transistor TR2. The transistor TR2 may be, for example, a transistor connected to a power supply line, or may be a transistor provided in the input/output circuit 11. In the peripheral region PR, the bonding layer B2 includes a conductive layer 25, and the memory layer 200 includes conductive layers 24 and 26, and contacts V1, V2, and C3. The conductive layer 26 is a wiring provided in the same layer as the conductive layer 23. At least one contact C3 is provided on the conductive layer 26. An upper portion of each contact C3 reaches at least a height of the conductive layer 211. An upper portion of each contact C3 is covered with the conductive layer 303 and is electrically connected to the conductive layer 303. Accordingly, the conductive layer 303 in the peripheral region PR is electrically connected to the transistor TR2 via at least one contact C3, the conductive layers 24 to 26 and 103 to 105, and the contacts V1, V2, C1, and C2.

In the wall region WR, the memory device 1 includes contacts C1W, C2W, C3W, V1W, and V2W, and conductive layers 103W, 104W, 105W, 24W, 25W, and 26W for each of the sealing portions ES1 and ES2. The contacts C1W, C2W, C3W, V1W, and V2W are provided in the same layer as the contacts C1, C2, C3, V1, and V2, respectively. The conductive layers 103W, 104W, 105W, 24W, 25W, and 26W are provided in the same layer as the conductive layers 103, 104, 105, 24, 25, and 26, respectively. Although not shown, the sets of the contacts C1W, C2W, C3W, V1W, and V2W and the conductive layers 103W, 104W, 105W, 24W, 25W, and 26W are provided in an annular shape in a plan view. That is, each of the sealing portions ES1 and ES2 is provided in the wall region WR in a quadrangular ring shape to surround the outer periphery of the core region CR and surrounds the peripheral region PR. The sealing portion ES2 is disposed outside the sealing portion ES1.

In the wall region WR, the semiconductor substrate W1 includes a P-type well region PW and an N-type well region NW. The P-type well region PW is a P-type impurity diffusion area (p+) provided in the vicinity of the upper surface of the semiconductor substrate W1. The N-type well region NW is an N-type impurity diffusion area (n+) provided in the vicinity of the upper surface of the semiconductor substrate W1. The P-type well region PW and the N-type well region NW correspond to the sealing portions ES1 and ES2, respectively. The conductive layer 303 in the wall region WR is connected to the P-type well region PW via the contacts C1W, C2W, C3W, V1W, and V2W, and the conductive layers 103W, 104W, 105W, 24W, 25W, and 26W corresponding to the sealing portion ES1. In addition, the conductive layer 303 in the wall region WR is connected to the N-type well region NW via the contacts C1W, C2W, C3W, V1W, and V2W, and the conductive layers 103W, 104W, 105W, 24W, 25W, and 26W corresponding to the sealing portion ES2.

The sealing portions ES1 and ES2 described above are structures capable of dissipating a positive charge and a negative charge generated inside and outside the wall region WR to the semiconductor substrate W1. Furthermore, each of the sealing portions ES1 and ES2 can reduce the penetration of moisture and the like from the outside of the wall region WR into the core region CR. Each of the sealing portions ES1 and ES2 can reduce stress generated in an interlayer insulating film (for example, tetraethoxysilane (TEOS)) of the memory device 1. In addition, each of the sealing portions ES1 and ES2 can also be used as a crack stopper.

### 7: Planar Layout of Wiring Layer 300

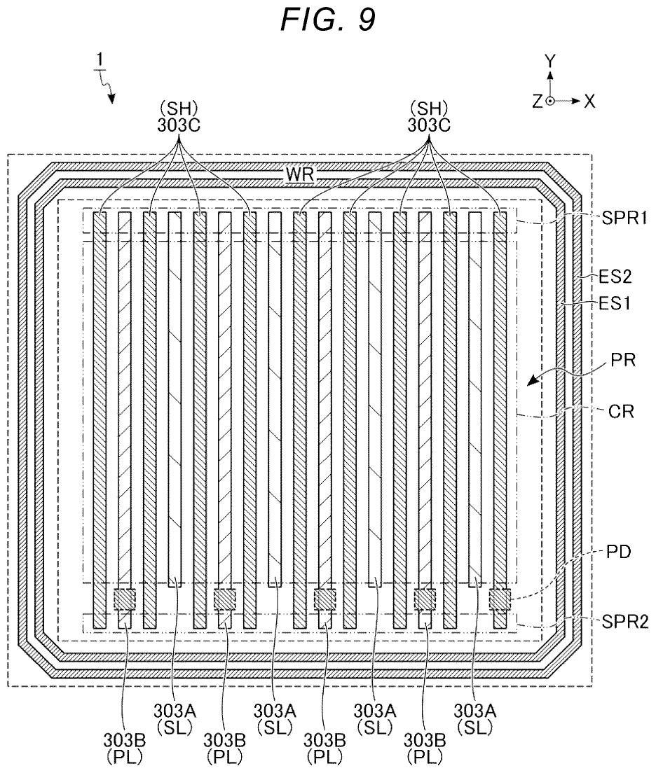

FIG. 9 is a plan view showing an example of a planar layout of the wiring layer 300 in the memory device 1 according to the embodiment. FIG. 9 shows the core region CR, the peripheral region PR, and the wall region WR, and a part of the wiring and the pad PD extracted. As shown in FIG. 9, in the wall region WR, the sealing portion ES1 surrounds the outer periphery of the core region CR and the peripheral region PR. The sealing portion ES2 surrounds the outer periphery of the sealing portion ES1.

The peripheral region PR includes sub-regions SPR1 and SPR2. Each of the sub-regions SPR1 and SPR2 is a region extending along the X direction. The sub-regions SPR1 and SPR2 interpose the core region CR in the Y direction. A plurality of conductive layers 303 are disposed inside the wall region WR. Each of the plurality of conductive layers 303 has a portion that extends in the Y direction. The plurality of conductive layers 303 are arranged in the X direction.

The plurality of conductive layers 303 include a conductive layer 303A used as a part of the source line SL, a conductive layer 303B used as a part of the power supply line PL, and a conductive layer 303C used as a part of the shield line SH. The conductive layer 303A overlaps each of the core region CR and the sub-region SPR1. The conductive layer 303B overlaps each of the core region CR and the sub-regions SPR1 and SPR2. The conductive layer 303C overlaps each of the core region CR and the sub-regions SPR1 and SPR2.

The conductive layers 303C are disposed every other one of the plurality of conductive layers 303 arranged in the X direction. The conductive layer 303A is disposed between two conductive layers 303C adjacent to each other in the X direction. The conductive layer 303B is disposed between two conductive layers 303C adjacent to each other in the X direction. The conductive layer 303A and the conductive layer 303B are disposed not to be adjacent to each other between the two conductive layers 303C adjacent to each other in the X direction. In other words, the conductive layer 303A is disposed at the (4×k)th position among the plurality of conductive layers 303 arranged in the X direction. The conductive layer 303B is disposed at the (4×k−2)th position among the plurality of conductive layers 303 arranged in the X direction. The conductive layer 303C is disposed at the (2×k−1)th position (k is an integer equal to or greater than 1) among the plurality of conductive layers 303 arranged in the X direction. The type of the conductive layers 303 disposed on both end sides in the X direction may be any one of the conductive layers 303A, 303B, and 303C.

The plurality of pads PD are disposed, for example, between the core region CR and the sub-region SPR2. One pad PD is connected to each conductive layer 303B. A power supply voltage, a ground voltage, and the like are applied to the pad PD connected to the conductive layer 303B. One pad PD is connected to at least one conductive layer 303C. The pads PD, not shown, can be connected to the input/output circuit 11, the logic controller 12, and the like. Further, the pad PD may be connected to the conductive layer 303A.

### 8: Planar Layout of Source Lines SL, Power Supply Lines PL, and Shield Lines SH

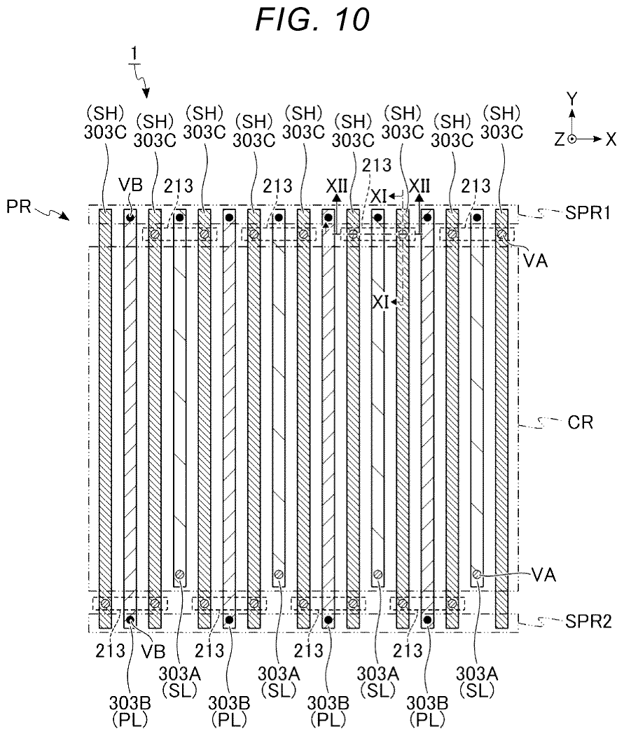

FIG. 10 is a plan view showing an example of a planar layout of source lines SL, power supply lines PL, and shield lines SH in the memory device 1 according to the embodiment. As shown in FIG. 10, each conductive layer 303A is connected to a via VB in the sub-region SPR1, and is connected to a via VA in the core region CR. Each conductive layer 303B is connected to the via VB in each of the sub-regions SPR1 and SPR2. The plurality of conductive layers 303C are electrically connected by utilizing the plurality of conductive layers 213 spaced apart from each other in the same layer. Specifically, two conductive layers 303C (shield lines SH) adjacent to each other in the X direction are electrically connected via the conductive layer 213.

More specifically, among the plurality of conductive layers 303C arranged in the X direction, the conductive layer 303C disposed at the (2×1−1)th position (i is an integer equal to or greater than 1) from the end portion and the conductive layer 303C disposed at the (2×i)th position from the end portion are connected via a conductive layer 213 disposed between the core region CR and the sub-region SPR2. The conductive layer 303C disposed at the (2×i)th position from the end portion and the conductive layer 303C disposed at the (2×i+1)th position from the end portion are connected via a conductive layer 213 disposed between the core region CR and the sub-region SPR1.

In other words, from the end portion in the X direction, the conductive layer 303C disposed at the (2×i−1)th position and the conductive layer 303C disposed at the (2×i)th position are electrically connected via the conductive layer 213 in the region on the sub-region SPR2 side outside the core region CR, and the conductive layer 303C disposed at the (2×i)th position and the conductive layer 303C disposed at the (2×i+1)th position are electrically connected via the conductive layer 213 in the region on the sub-region SPR1 side outside the core region CR.

In the memory device 1, the disposition of the sub-regions SPR1 and SPR2 may be interchanged. The associated conductive layer 213 and conductive layer 303C are connected through a via VA. In this way, the plurality of conductive layers 303C arranged in the X direction are electrically connected by alternately utilizing between the conductive layer 213 provided on one side in the Y direction and the conductive layer 213 provided on the other side in the Y direction. In other words, the plurality of conductive layers 303C are short-circuited to each other via the conductive layer 213 provided in a layer different from the wiring layer 300.

### 9: Cross-Sectional Structure of Shield Line SH and its Vicinity

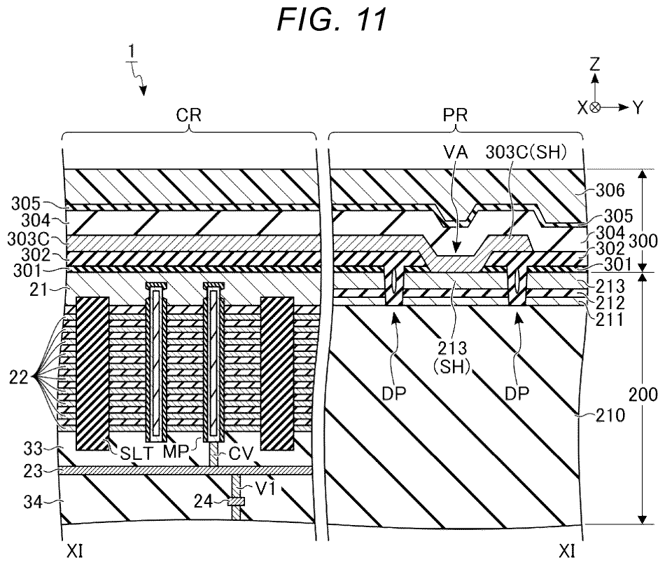

FIG. 11 is a cross-sectional view taken along line XI-XI in FIG. 10, showing an example of a cross-sectional structure of the shield line SH and its vicinity provided in the memory device 1 according to the embodiment. As shown in FIG. 11, the conductive layer 303C is disposed above the conductive layer 21 in the core region CR, and is connected to the conductive layer 213 through a via VA in the peripheral region PR. The conductive layer 213 is divided by dividing portions DP into the shape shown in FIG. 10. The dividing portion DP divides the conductive layer 211, the sacrificial member 212, and the conductive layer 213. The dividing portion DP electrically separates the conductive layer 21 (source line SL) provided in the core region CR from the conductive layers 213 and 211 provided in the peripheral region PR. The dividing portion DP is formed, for example, after the insulator layer 301 is formed. An insulator layer 302 is embedded in the dividing portion DP. The dividing portion DP may include a gap.

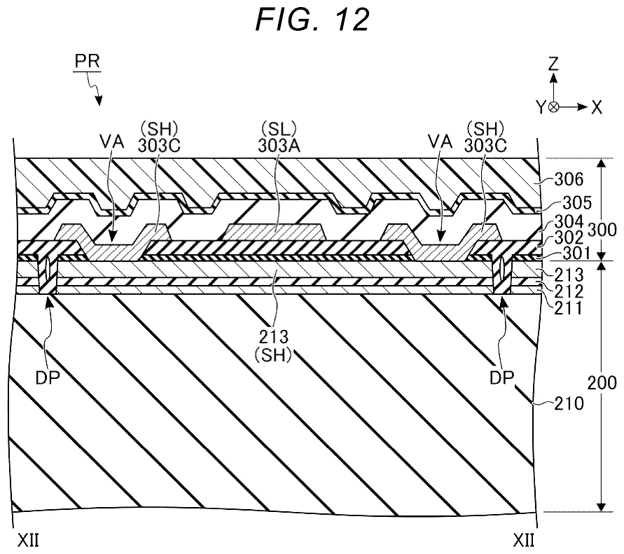

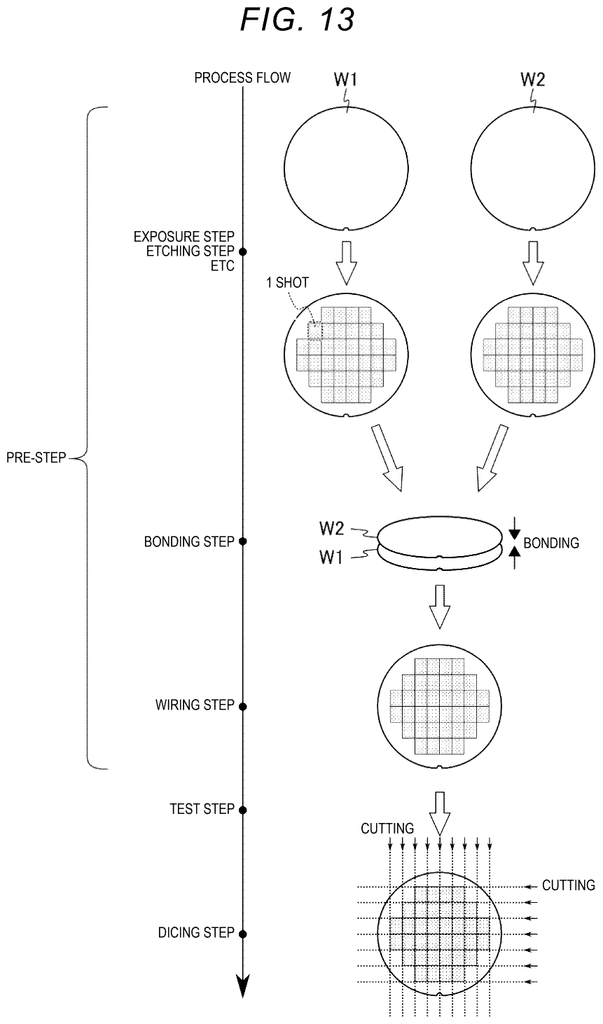

FIG. 12 is a cross-sectional view taken along line XII-XII in FIG. 10, showing an example of a cross-sectional structure of the shield line SH and its vicinity provided in the memory device 1 according to the embodiment. As shown in FIG. 12, the conductive layer 213 connected to the shield line SH contacts two different conductive layers 303C connected to one end portion and the other end portion in the X direction through vias VA. A conductive layer 303A used as a part of the source line SL or a conductive layer 303B used as a part of the power supply line PL may be disposed above the conductive layer 213 connected to the shield line SH. In this way, in the conductive layer 213 connected to the shield line SH (conductive layer 303C), any of the conductive layers 303A and 303B may overlap in the Z direction depending on the layout of the plurality of conductive layers 303 to intersect with each other, for example, in the planar layout shown in FIG. 10.

### <2> Manufacturing Method

Next, a manufacturing method of the memory device 1 according to the embodiment will be described.

### <2-1> Overview of Manufacturing Method of Memory Device 1

FIG. 13 is a schematic view showing an overview of a manufacturing method of the memory device 1 according to the embodiment. A general process flow in the manufacturing method of the memory device 1 will be described below with reference to FIG. 13.

First, semiconductor substrates W1 and W2 are prepared. Then, an exposure step, an etching step, and the like are executed on the semiconductor substrate W1, and the CMOS layer 100 and the bonding layer B1 are formed on the semiconductor substrate W1. Similarly, an exposure step, an etching step, and the like are executed on the semiconductor substrate W2, and the memory layer 200 and the bonding layer B2 are formed on the semiconductor substrate W2. The exposure process is a process of transferring a pattern of a mask (reticle) onto a resist material on a wafer in shot units. A “shot” corresponds to a partitioned area of exposure in an exposure process. In the exposure process, one shot of exposure is repeatedly executed at different positions. The shot disposition of the semiconductor substrate W1 and the shot disposition of the semiconductor substrate W2 are set to be the same.

Thereafter, a step of bonding the semiconductor substrates W1 and W2 is executed. Accordingly, the front surface (bonding layer B1) of the semiconductor substrate W1 and the front surface (bonding layer B2) of the semiconductor substrate W2 are bonded to each other. Then, for example, after the semiconductor substrate W2 is removed, a wiring step is executed. In the wiring step, a wiring (for example, the conductive layer 303) or a pad PD used for external connection to a circuit formed using the semiconductor substrates W1 and W2 is formed. The series of steps described above corresponds to a pre-step.

The semiconductor substrate W1 on which the pre-step has completed has a plurality of memory devices 1. A test step is executed for these memory devices 1, and it is determined whether the memory device 1 of the semiconductor substrate W1 is defective. Thereafter, a dicing step is executed. The dicing step is a process of separating the memory devices 1 into chip units by cutting the semiconductor substrate W1 (wafer) based on the shots and the disposition of the memory devices 1 in the shots. Accordingly, one chip of the memory device 1 is formed. The chips of the memory device 1 are distinguished as to whether they are non-defective products based on the results of the test step.

### <2-2> Overview of Test Method

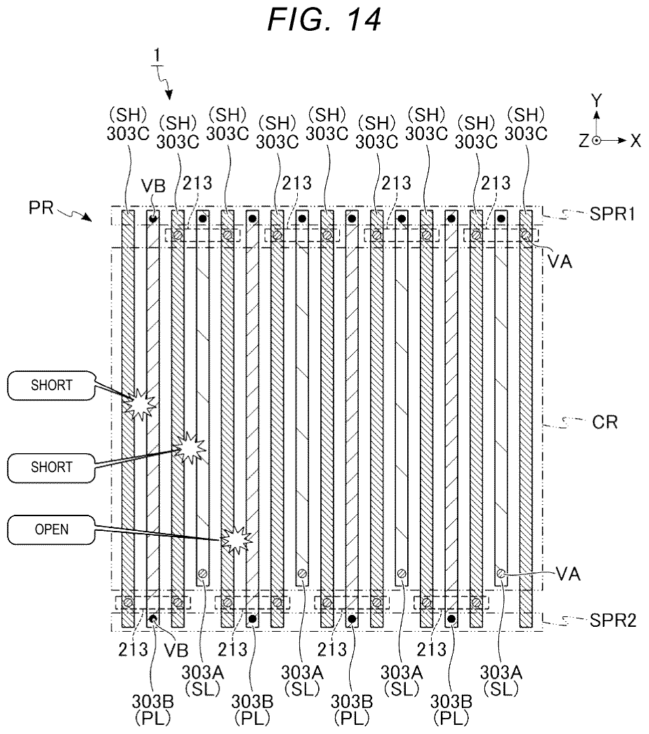

FIG. 14 is a plan view illustrating an overview of a test method of the memory device 1 according to the embodiment. FIG. 14 illustrates a case where a defect occurs in the conductive layer 303 for the planar layout of the memory device 1 shown in FIG. 10. As shown in FIG. 14, a short defect may occur between adjacent conductive layers 303A (source lines SL) and conductive layers 303C (shield lines SH), or between adjacent conductive layers 303B (power supply lines PL) and conductive layers 303C (shield lines SH). An open defect may occur in each of the conductive layers 303A, 303B, and 303C, to straddle the plurality of conductive layers 303 arranged in the X direction.

In the present example, the respective conductive layers 303A are electrically connected via a conductive layer 21 (not shown). The respective conductive layers 303C are electrically connected to each other. Therefore, a short defect between the adjacent conductive layers 303A and 303C can be detected by checking the electrical connection between the source line SL and the shield line SH in the test step.

On the other hand, the respective conductive layers 303B are independent of each other. Therefore, a short defect between the adjacent conductive layers 303B and 303C can be detected by checking the electrical connection between each power supply line PL and the shield line SH in the test step.

Furthermore, when an open defect occurs in any of the conductive layers 303A, 303B, and 303C, the current-voltage characteristics of the shield line SH change. Therefore, an open defect in each conductive layer 303 can be detected, for example, by charging the shield line SH in a test step and based on a discharge rate of the charged shield line SH.

### <3> Effects of Embodiment

According to an embodiment, it is possible to improve the detection accuracy for gap defects on a bonding surface of the memory device 1 having a bonding structure. The effects of the embodiment will be described in detail below.

When dicing step is executed on a semiconductor substrate having gap defects generated at the bonding surface, contamination of the device may occur. Therefore, ultrasonic inspection or optical inspection is performed in advance on all wafers to detect gap defects occurring on the bonding surface and screen wafers in which the gaps are generated. However, the total inspection on wafers places a heavy load on the inspection device. In order to reduce the load on the inspection device, it is desirable to also perform detection by a die sort (D/S) test, but gaps may occur in places that cannot be detected by die sorting.

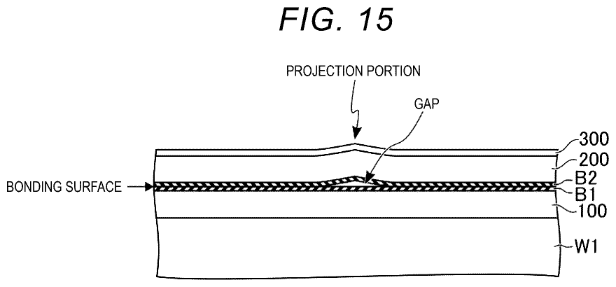

FIG. 15 is a cross-sectional view showing an example of a gap defect occurring in a memory device having a bonding structure. FIG. 15 illustrates a case where a gap (film floating void) occurs between the bonding layer B1 and the bonding layer B2 corresponding to the bonding surface. In such a case, projection portions that conform to the shape of the gaps may be formed in the bonding layer B2, the memory layer 200, and the wiring layer 300. Such a projection portion can cause defocusing in the lithography step for forming the wiring layer 300. Therefore, when a defect (for example, a short defect and an open defect) caused by defocus in the wiring layer 300 is detected in the inspection step, it can be assumed that a gap defect has occurred in the bonding surface.

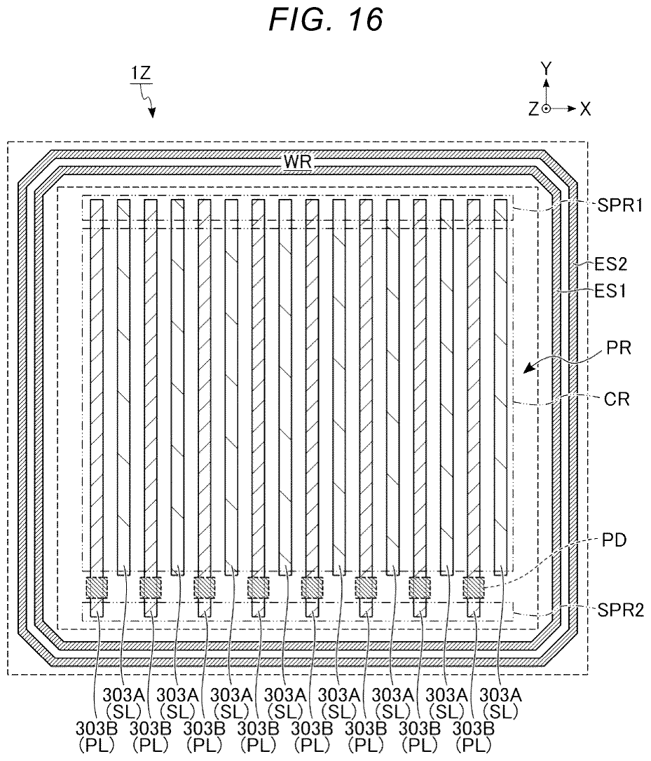

FIG. 16 is a plan view showing an example of a planar layout of the wiring layer 300 in a memory device 1Z according to a comparative example. As shown in FIG. 16, a memory device 1Z has a configuration in which the conductive layer 303C (shield line SH) is omitted from the layout of the memory device 1 shown in FIG. 9. In the layout of the conductive layer 303 in the memory device 1Z, the power supply lines PL and the source lines SL are disposed alternately. Therefore, a short defect between adjacent power supply lines PL and source lines SL can be detected by checking whether the source lines SL and power supply lines PL are electrically connected. Meanwhile, in the comparative example, it is difficult to detect an open defect that occurs in any of the power supply line PL and the source line SL. In this way, even if defocus occurs due to a gap on the bonding surface, it may be difficult to detect the gap on the bonding surface by die sorting.

In contrast, in the memory device 1 according to the embodiment, a shield line SH (conductive layer 303C) for detecting open defects/short defects caused by gaps is added to the wiring layer 300. The shield lines SH are disposed alternately with the source lines SL or the power supply lines PL. The plurality of shield lines SH arranged in the X direction are electrically connected to each other.

Accordingly, a short defect between the source line SL and the shield line SH can be detected by checking whether adjacent source lines SL and shield lines SH are electrically connected. Moreover, by checking whether adjacent power supply lines PL and shield lines SH are electrically connected, short defects between the power supply lines PL and shield lines SH can be detected. Furthermore, by checking the electrical characteristics after charging the shield line SH at the pad PD provided in correspondence with the shield line SH (the conductive layer 303C), it is possible to check whether an open defect has occurred in the plurality of conductive layers 303.

As a result, in the memory device 1 according to the embodiment, a test step utilizing the plurality of conductive layers 303 can detect whether a short defect and/or an open defect has occurred in the wiring layer 300. In this way, the memory device 1 according to the embodiment can improve the detection accuracy for gap defects on a bonding surface of the memory device 1 having a bonding structure. Therefore, the memory device 1 according to the embodiment makes it possible to detect gap defects on the bonding surface that pose a risk in the dicing step, and reduce the load (capacity or the like) of in-line inspection.

### <4> Modification Examples ETC.

The memory device 1 described above may be modified in various ways.

### First Modification Example

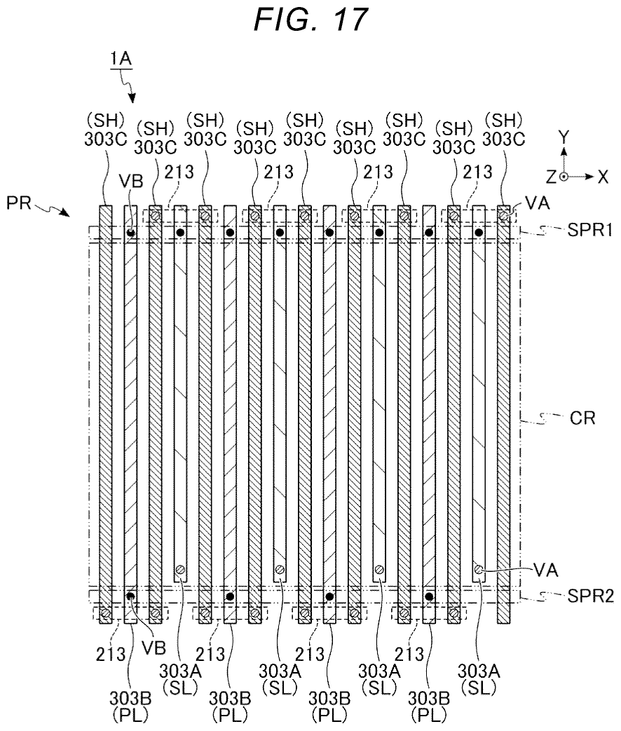

FIG. 17 is a plan view showing an example of a planar layout of source lines SL, power supply lines PL, and shield lines SH in a memory device 1A according to a first modification example of the embodiment. FIG. 17 shows an extract of the similar configuration as in FIG. 10. As shown in FIG. 17, the memory device 1A differs from the memory device 1 in the disposition of the sub-regions SPR1 and SPR2. Specifically, in the memory device 1A, the sub-region SPR1 is disposed between a plurality of conductive layers 213 disposed on one end side in the Y direction (the upper side on the paper surface) and the core region CR. In addition, in the memory device 1A, the sub-region SPR2 is disposed between a plurality of conductive layers 213 disposed on the other end side in the Y direction (the lower side on the paper surface) and the core region CR.

In this manner, the respective dispositions of the sub-regions SPR1 and SPR2 may be changed.

### Second Modification Example

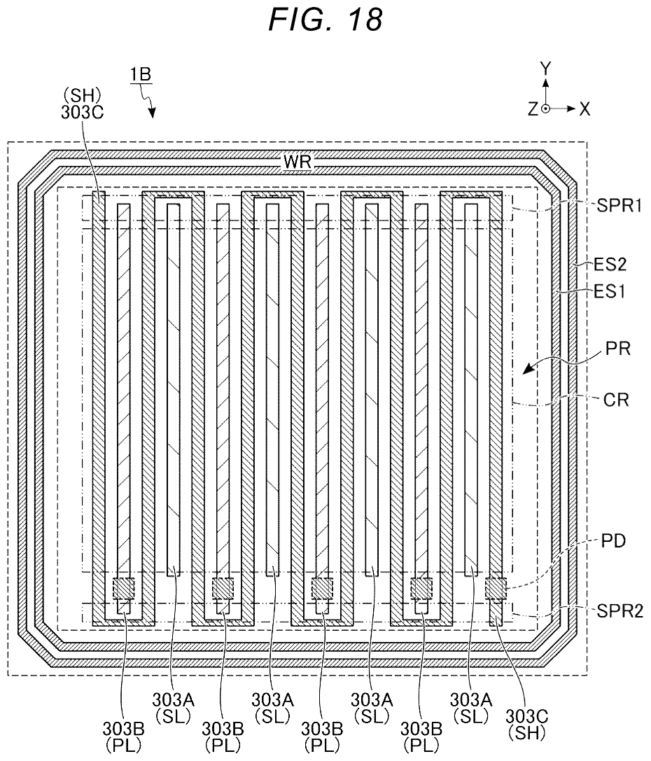

FIG. 18 is a plan view showing an example of a planar layout of source lines, power supply lines, and shield lines in a memory device 1B according to a second modification example of the embodiment. FIG. 18 shows an extract of the similar configuration as in FIG. 9. As shown in FIG. 18, the memory device 1B is different from the memory device 1 in the shape of the conductive layer 303C. Specifically, the conductive layer 303C in the memory device 1B has a structure in which the plurality of conductive layers 303C shown in FIG. 9 are continuously provided in the same layer with those portions within the peripheral region PR interposed therebetween.

Specifically, in the memory device 1B, a portion of the conductive layer 303C disposed at the (2×i−1)th position (i is an integer equal to or greater than 1) and a portion of the conductive layer 303C disposed at the (2×i)th position from the end portion in the X direction are provided continuously along the end portion of the conductive layer 303B (the lower side of the paper surface). In the memory device 1B, a portion of the conductive layer 303C disposed at the (2×i)th position and a portion of the conductive layer 303C disposed at the (2×i+1)th position from the end portion in the X direction are provided continuously along the end portion of the conductive layer 303A (the upper side of the paper surface). In other words, in the present example, in the conductive layer 303C, the plurality of portions of the conductive layer 303C extending in the Y direction and arranged in the X direction are continuously provided with first portions provided along one end of any of the conductive layers 303A and 303B and second portions provided along the other end of any of the conductive layers 303A and 303B alternately interposed therebetween. In this manner, the conductive layer 303C may be provided integrally without utilizing the conductive layer 213.

### Others

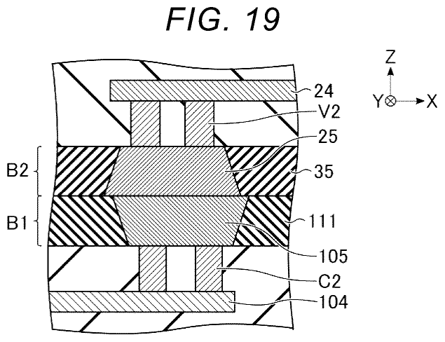

FIG. 19 is a cross-sectional view showing an example of a detailed cross-sectional structure of the vicinity of two bonding pads disposed opposite to each other in the memory device 1 according to the embodiment. FIG. 19 shows a conductive layer 105 (bonding pad) formed by utilizing a semiconductor substrate W1 (not shown), a conductive layer 25 (bonding pad) formed by utilizing a semiconductor substrate W2 (not shown), and some of the contacts C2 and V2 and the conductive layers 104 and 24 connected thereto. As shown in FIG. 19, two bonding pads disposed opposite to each other may have different taper shapes based on the etching direction in which they are formed. Specifically, the conductive layer 105 formed by utilizing the semiconductor substrate W1 has, for example, an inverted taper shape. The conductive layer 25 formed by utilizing the semiconductor substrate W2 has, for example, a taper shape. Therefore, the cross section along the Z direction at the portion where the conductive layer 105 and the conductive layer 25 are bonded may have a non-rectangular shape rather than a straight side wall. Furthermore, a set of two bonding pads disposed opposite to each other may be bonded with a deviation depending on the alignment during the bonding process. Therefore, a step may be formed between the side surface of the conductive layer 105 and the side surface of the conductive layer 25. The set of the two bonding pads disposed opposite to each other may have a boundary or may be integrated. The bonding pads and the contacts C2 and V2 connected to the bonding pads may be formed integrally. A plurality of corresponding contacts C2 and V2 may be connected to a bonding pad. For example, the conductive layer 105 may be connected to the conductive layer 104 via a plurality of contacts C2. Similarly, the conductive layer 25 may be connected to the conductive layer 24 via a plurality of contacts V2.

In the embodiment, the circuit configuration, the planar layout, and the cross-sectional structure of the memory device 1 may each be changed as appropriate. Other contacts may be inserted between the memory pillar MP and the conductive layer 23. Other contacts may be inserted between the contact C3 and the conductive layer 26. A conductive layer may be inserted between the connecting portions of the plurality of contacts. The number of wiring layers and contacts provided in the memory device 1 can be changed as appropriate depending on the circuit design. The memory pillar MP and each contact may have a taper shape, an inverted taper shape, or a bowing shape. The XY cross-sectional structure of the memory pillar MP may be circular or elliptical. Each wiring in the stacked wiring may include a metal oxide film around a conductor such as tungsten. In a stacked wiring, the conductive layers that are alternately stacked with the insulator layers may be considered as a configuration including such a metal oxide film.

In the present specification, “connected” refers to being electrically connected, and does not exclude, for example, having another element therebetween. The term “electrically connected” may be used via an insulator as long as it is capable of operating similarly to an electrically connected one. The “semiconductor substrate” may also be referred to simply as a “substrate”. The “semiconductor layer” may also be referred to as a “conductive layer”. The “area” may be considered to be a configuration included by the substrate. For example, when the semiconductor substrate W1 is defined as including a memory area MA and a contact area CA, the memory area MA and the contact area CA are respectively associated with different areas above the semiconductor substrate W1. The “height”, for example, corresponds to an interval in the Z direction between the configuration to be measured and the semiconductor substrate W1. As the reference for the “height”, a configuration other than the semiconductor substrate W1 may be used. The “top (plan) view”, for example, corresponds to viewing the front surface of the semiconductor substrate W1 from a vertical direction of the semiconductor substrate W1.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory device comprising:
a substrate;
a first circuit layer provided between the substrate and a bonding surface and including a first circuit;
a second circuit layer provided above the bonding surface and including a second circuit; and
a wiring layer provided above the second circuit layer and including a plurality of first wirings and a plurality of second wirings, each of the first and second wirings extending in a first direction,
wherein the plurality of first wirings are electrically connected to at least one of the first circuit or the second circuit,
the plurality of second wirings are electrically connected to each other, and
the first wirings and the second wirings are arranged alternately in a second direction along a substrate surface of the substrate, the second direction intersecting the first direction.

2. The memory device according to claim 1,
wherein the second circuit layer includes a plurality of first conductive layers spaced apart from each other in a same layer, and
two second wirings adjacent to each other in the second direction are electrically connected via one of the first conductive layers.

3. The memory device according to claim 2,
wherein the second circuit includes a memory cell array, and
the first circuit includes a CMOS circuit configured to control the memory cell array.

4. The memory device according to claim 3,
wherein the memory cell array includes a plurality of second conductive layers arranged in a third direction intersecting the substrate surface, a third conductive layer provided above the plurality of second conductive layers, and a memory pillar penetrating the plurality of second conductive layers, intersections of the plurality of second conductive layers and the memory pillar functioning as memory cells, and an end portion of the memory pillar being connected to the third conductive layer, and
a height of an upper surface of each of the plurality of first conductive layers is aligned with a height of an upper surface of the third conductive layer.

5. The memory device according to claim 4,
wherein the memory pillar includes a semiconductor layer extending in the third direction, and
the semiconductor layer and the third conductive layer are electrically connected via a side surface of the memory pillar.

6. The memory device according to claim 5,
wherein the second circuit layer further includes a plurality of fourth conductive layers provided below the plurality of first conductive layers respectively, and a member provided between the first conductive layers and the fourth conductive layers adjacent to each other in the third direction,
a height of a lower surface of each of the plurality of fourth conductive layers is aligned with a height of a lower surface of the third conductive layer, and
a height of the member is same as a height at which the third conductive layer and the semiconductor layer are connected.

7. The memory device according to claim 6, wherein the second circuit layer further includes an insulating member separating the third conductive layer from each of the plurality of first conductive layers and the plurality of fourth conductive layers.

8. The memory device according to claim 4,
wherein the substrate includes a first region and a second region arranged in the first direction, and a third region overlapping the memory cell array in the third direction between the first region and the second region,
each of the plurality of first wirings and the plurality of second wirings includes a portion overlapping the third region in the third direction, and
the plurality of first wirings are electrically connected to the first circuit via the second circuit other than the memory cell array, the second circuit other than the memory cell array overlapping at least one of the first region and the second region in the third direction.

9. The memory device according to claim 8, wherein the plurality of first wirings include at least one signal line and a plurality of power supply lines.

10. The memory device according to claim 9, wherein, in the plurality of first wirings, signal lines and the power supply lines are alternately arranged in the second direction.

11. The memory device according to claim 9, wherein the signal line is electrically connected to the third conductive layer at a portion overlapping the third region in the third direction.

12. The memory device according to claim 9, wherein the plurality of power supply lines are electrically connected to the first circuit via portions of the second circuit, the portions overlapping the first region and the second region respectively in the third direction.

13. The memory device according to claim 9, wherein the wiring layer further includes a plurality of pads each having an exposed upper surface, the pads being associated with each of the plurality of power supply lines.

14. The memory device according to claim 8,
wherein, among the plurality of second wirings, a second wiring disposed at a (2×i−1)^{th} position (i is an integer equal to or greater than 1) from an end portion in the second direction and a second wiring disposed at a (2×i)^{th} position from the end portion are electrically connected via a first one of the first conductive layers, the first one of the first conductive layers being provided not to overlap the third region in the third direction on a side of the first region in the first direction, and
among the plurality of second wirings, the second wiring disposed at the (2×i)^{th} position from the end portion and a second wiring disposed at a (2×i+1)^{th} position from the end portion are electrically connected via a second one of the first conductive layers, the second one of the first conductive layers being provided not to overlap the third region in the third direction on a side of the second region in the first direction.

15. The memory device according to claim 14,
wherein the first one of the first conductive layers overlaps a corresponding first wiring among the plurality of first wirings in the third direction, and
the first one of the first conductive layers intersects the first wiring when viewed from the third direction.

16. The memory device according to claim 8, further comprising: a sealing portion continuously provided from the substrate to the wiring layer and surrounding an outer periphery of the first region, the second region, and the third region in a plan view.

17. The memory device according to claim 1, wherein the plurality of second wirings are continuously provided with a plurality of first portions provided along one end of the plurality of first wirings and a plurality of second portions provided along the other end of the plurality of first wirings alternately interposed therebetween, the plurality of first portions and the plurality of second portions being included in the wiring layer together with the plurality of second wirings.

18. The memory device according to claim 1, wherein the wiring layer further includes a pad having an exposed upper surface, the pad being associated with one of the plurality of second wirings.

19. The memory device according to claim 18, wherein electrical characteristics of the pad change depending on whether an open defect occurs in the plurality of first wirings and the plurality of second wirings.

20. The memory device according to claim 1, further comprising:
a first pad provided adjacent to the bonding surface and electrically connected to the first circuit; and
a second pad provided adjacent to the bonding surface and electrically connected between the first pad and the second circuit,
wherein a taper direction of the first pad is different from a taper direction of the second pad.
